(19) United States
(12) Patent Application Publication
(10) Pub. No.: US 2024/0282686 A1
(43) Pub. Date: Aug. 22, 2024

(54) 3D Stacking Structure and Method of Fabricating the Same

(71) Applicant: Taiwan Semiconductor Manufacturing Co., Ltd., Hsinchu (TW)

(72) Inventors: Tzuan-Horng Liu, Longtan Township (TW); An-Jhih Su, Taoyuan City (TW); Hao-Yi Tsai, Hsinchu (TW); Tsung-Yuan Yu, Taipei City (TW); Po-Yuan Teng, Hsinchu (TW); Chung-Ming Weng, Hsinchu (TW); Che-Hsiang Hsu, Taichung City (TW)

(21) Appl. No.: 18/327,220

(22) Filed: Jun. 1, 2023

Related U.S. Application Data
(60) Provisional application No. 63/485,705, filed on Feb. 17, 2023.

(51) Int. Cl. H01L 23/498; H01L 21/48; H01L 21/60

(52) U.S. Cl. CPC H01L 23/49827; H01L 21/485; H01L 21/60; H01L 23/49883; H01L 2021/6027

(57) ABSTRACT

A method includes forming a first package component and a second package component. The first package component includes a first polymer layer, and a first electrical connector, with at least a part of the first electrical connector being in the first polymer layer. The second package component comprises a second polymer layer, and a second electrical connector, with at least a part of the second electrical connector being in the second polymer layer. The first package component is bonded to the second package component, with the first polymer layer being bonded to the second polymer layer, and the first electrical connector being bonded to the second electrical connector.

### PRIORITY CLAIM AND CROSS-REFERENCE

This application claims the benefit of the following provisionally filed U.S. Patent application: Application No. 63/485,705, filed on Feb. 17, 2023, and entitled “3D Stacking Structure and Method of Fabricating the Same,” which application is hereby incorporated herein by reference.

### BACKGROUND

Integrated circuits are having increasingly more functions. In order to integrate more functions together, a plurality of device dies are manufactured, and are packaged together in a packaging process(es). The plurality of device dies bonded together are electrically interconnected.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-10 illustrate the cross-sectional views of intermediate stages in the formation of a package through bonding in accordance with some embodiments.

FIGS. 11-14 illustrate the cross-sectional views of intermediate stages in a polymer hybrid bonding process in accordance with some embodiments.

FIGS. 15-18 illustrate the cross-sectional views of intermediate stages in a polymer hybrid bonding process in accordance with some embodiments.

FIGS. 19-22 illustrate the cross-sectional views of intermediate stages in a polymer hybrid bonding process in accordance with some embodiments.

FIGS. 23-30 illustrate the cross-sectional views of some packages adopting the polymer bonding scheme in accordance with some embodiments.

FIG. 31 schematically illustrates bonded polymer layers in accordance with some embodiments.

FIG. 32 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package and the method of forming the same are provided. In accordance with some embodiments of the present disclosure, two package components are bonded through polymer hybrid bonding, which includes the bonding of electrical connectors to each other, and the bonding of polymer layers to each other. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

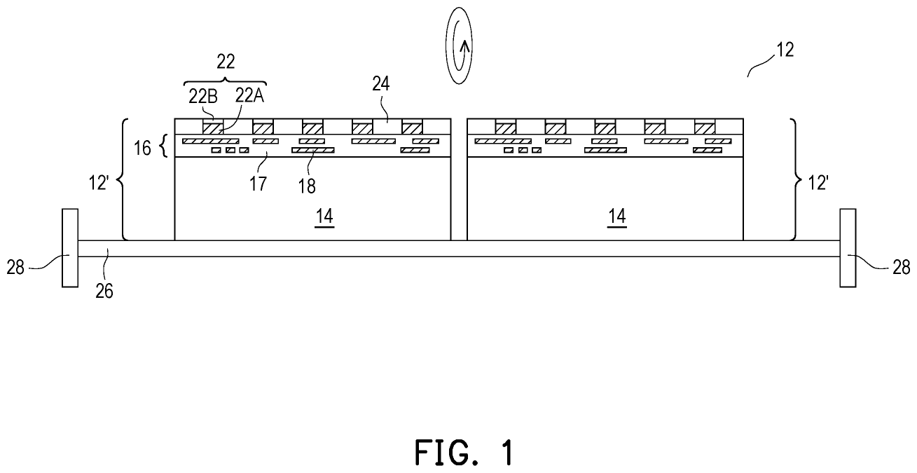

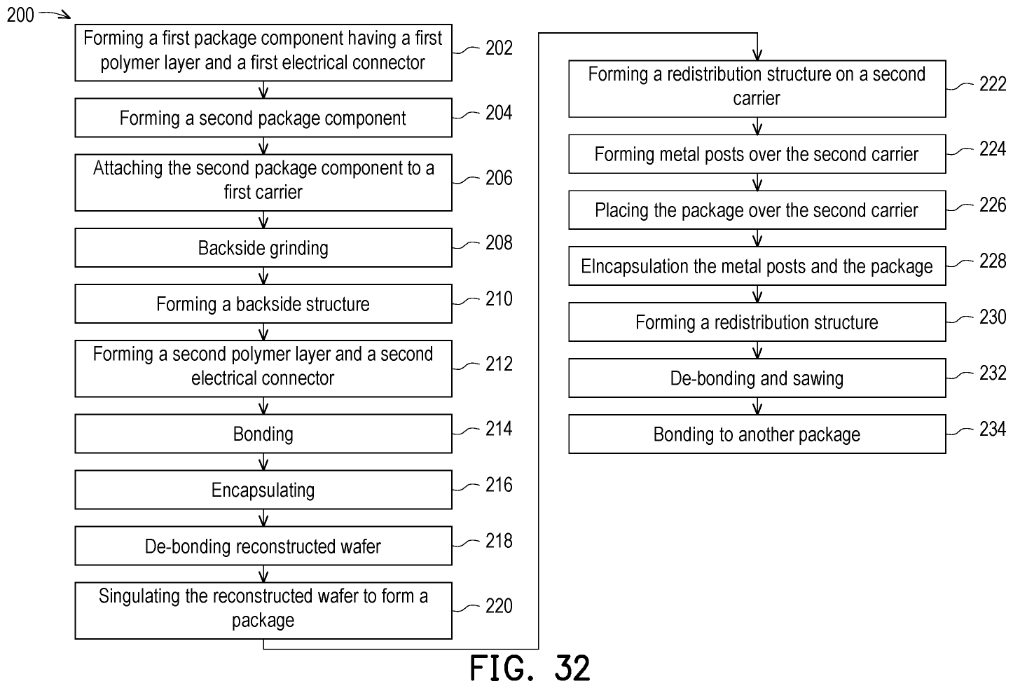

FIGS. 1 through 10 illustrate the cross-sectional views of intermediate stages in the formation of a package in accordance with some embodiments of the present disclosure. The corresponding processes are also reflected schematically in the process flow shown in FIG. 32.

FIG. 1 illustrates the formation of package component 12 in accordance with some embodiments. The respective process is illustrated as process 202 in the process flow 200 as shown in FIG. 32. In accordance with some embodiments, package component 12 comprises a wafer, and is referred to as wafer 12 hereinafter, which comprises device dies 12′ therein. In accordance with some embodiments, wafer 12 is an unsawed device wafer, which includes integrated circuits (including active devices such as transistors and passive devices such as resistors, capacitors, and/or the like). The wafer 12 may include a semiconductor substrate 14 (such as a silicon substrate) continuously extending into the device dies 12′. When wafer 12 is a device wafer, it may comprise interconnect structure 16, which may comprise dielectric layers 17, and metal lines and vias 18 formed through damascene processes. The dielectric layers 17 may comprise low-k dielectric layers.

In accordance with alternative embodiments, wafer 12 is a reconstructed wafer, which includes device dies and/or wafer(s) bonded together. The device dies are encapsulated in corresponding encapsulants, such as molding compounds, underfills, or the like. Redistribution lines (RDLs) (also referred to using reference numerals 18) may be formed as parts of the reconstructed wafer or the unsawed device wafer, and are electrically connected to the integrated circuits in wafer 12. The reconstructed wafer 12 may or may not include other package components such as interposers, package substrates, and/or the like.

In accordance with some embodiments, electrical connectors 22 are formed at the top surface of wafer 12. In accordance with some embodiments, electrical connectors 22 comprise non-solder conductive features 22A (such as metal pillars), which may be formed of copper, nickel, palladium, gold, or the like, combinations thereof, multi-layers thereof. There may be, or may not be, solder layers 22B over the non-solder conductive features 22A. The solder layers 22B may be formed of a lead-free solder such as SnAg.

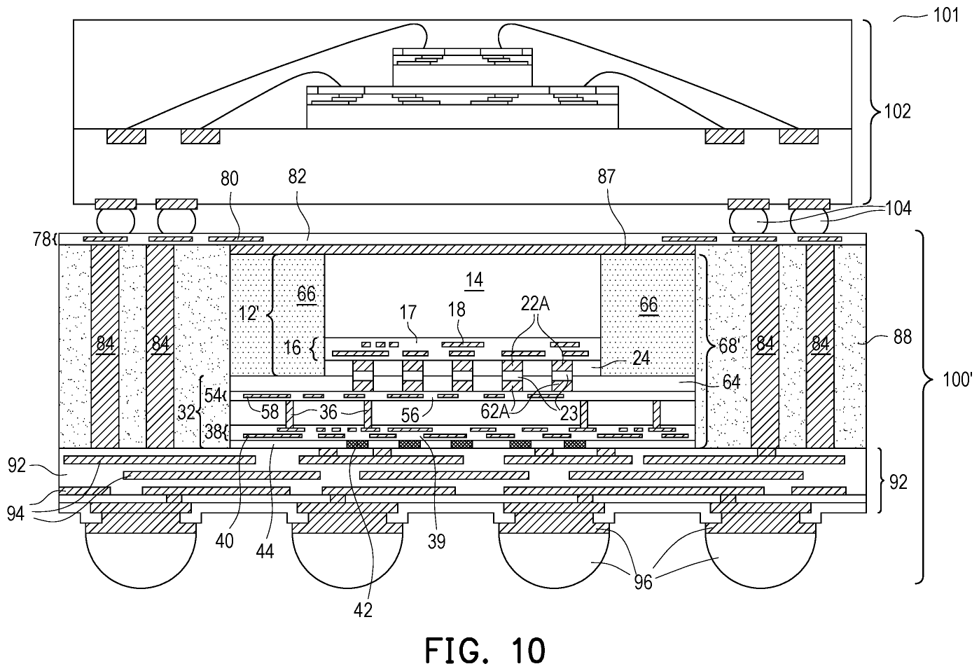

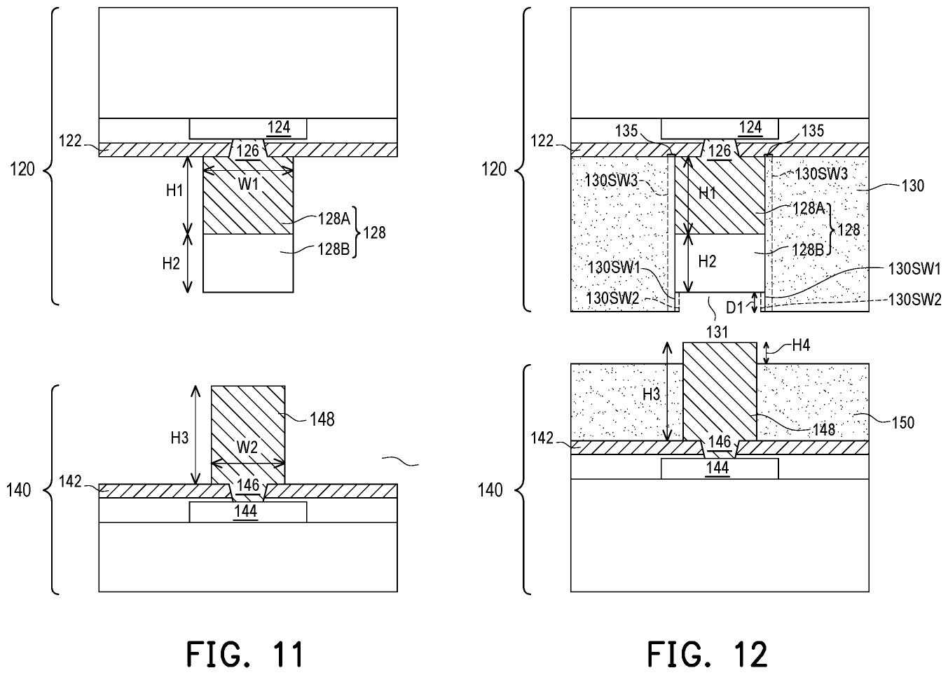

Polymer layer 24 is formed to encapsulate at least the lower parts, or the entireties, of electrical connectors 22. In accordance with some embodiments, polymer layer 24 is formed of or comprises polyimide, polybenzoxazole (PBO), benzocyclobutene (BCB), or the like. The details of the materials, the structures, and the formation process of electrical connectors 22 are discussed in detail referring to FIGS. 11 through 22.

Wafer 12 is placed on dicing tape 26, which is fixed on frame 28. A singulation process is performed, for example, through sawing using a blade, so that package components 12′ in wafer 12 are separated from each other. Depending on whether wafer 12 is an unsawed device wafer or a reconstructed wafer, package components 12′ may be device dies (also referred to as chips), packages, or the like. The packages may sometimes include a system that are formed of bonded device dies, and are sometimes referred to as System-on-Chip (SoC) packages or SoC dies. For example, the packages may include logic dies, memory dies, independent passive devices, or the like therein.

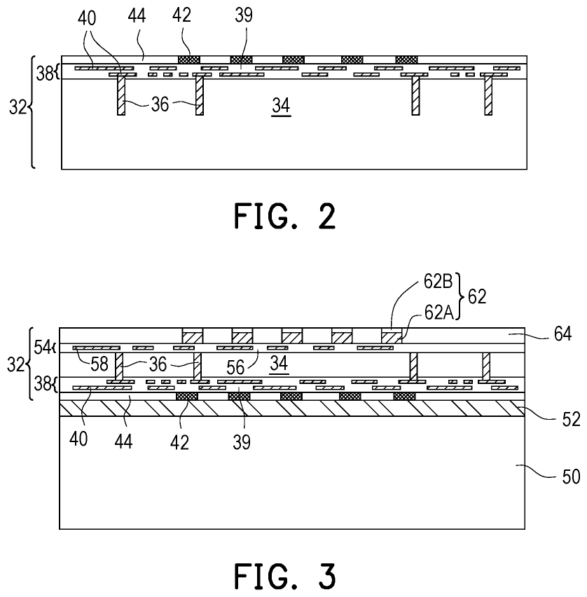

FIG. 2 illustrates the formation of package component 32 in accordance with some embodiments. The respective process is illustrated as process 204 in the process flow 200 as shown in FIG. 32. Package component 32 may be a wafer in accordance with some embodiments, and is referred to as wafer 32 hereinafter.

In accordance with some embodiments, wafer 32 is an interposer wafer, which is free from active devices such as transistors therein. The interposer wafer may also be free from (or may include) passive devices such as capacitors, resistors, inductors, and/or the like therein. In accordance with alternative embodiments, wafer 32 is an active wafer, with integrated circuit devices (not shown) formed therein. The integrated circuit devices may include active devices such as transistors, and may or may not include passive devices therein. In accordance with yet alternative embodiments, wafer 32 is a reconstructed wafer including device dies packaged therein

An example structure of device wafer 32 is discussed herein. In accordance with some embodiments, as shown in FIG. 2, device wafer 32 includes substrate 34. Through-substrate vias 36 (sometimes referred to as Through-Silicon Vias (TSVs) or Through-Semiconductor Vias (also TSVs)) extend from the front side (the illustrated top side) into substrate 34. Through-substrate vias 36 are encircled by dielectric insulation layers (not shown), which electrically insulate through-substrate vias 36 from substrate 34. Substrate 34 may be a semiconductor substrate such as a silicon substrate. In accordance with other embodiments, substrate 34 may include other semiconductor materials such as silicon germanium, carbon-doped silicon, or the like. Substrate 34 may be a bulk substrate.

In accordance with some embodiments, device wafer 32 includes device dies, which may include logic dies, memory dies, input-output dies, IPDs, or the like, or combinations thereof. The device dies in device wafer 32 may also include memory dies. Device wafer 32 may include semiconductor substrate 34 extending continuously into all the device dies 32′ in device wafer 32.

Over semiconductor substrate 34, interconnect structure 38 is formed. Interconnect structure 38 may include an Inter-Layer Dielectric (ILD) and Inter-Metal Dielectrics (IMDs), which IMDs may comprise low-k dielectric materials. Interconnect structure 38 further comprises conductive features 40 such as contact plugs, metal lines, vias, and the like. The contact plugs may be formed of or comprise tungsten, cobalt, titanium nitride, or the like. The metal lines and vias may be comprised in damascene structures.

FIG. 2 further illustrates the formation of dielectric layer 44, which may be formed of or comprise a silicon-containing dielectric material, polymer, or the like. Dielectric layer 44 may be formed of or comprise silicon oxide, silicon oxynitride, silicon carbide, silicon oxycarbide, silicon nitride, polyimide, PBO, BCB, or the like.

Electrical connectors 42 are formed in dielectric layer 44. Electrical connectors 42 may include bond pads, metal pillars, or the like, and may or may not include pre-solder layers. Electrical connectors 42 may have top surfaces coplanar with, higher than, or lower than, the top surface of dielectric layer 44. The formation of the corresponding electrical connectors 42 and dielectric layer 44 may include etching dielectric layer 44 and the underlying dielectric layer(s) to form openings, through which the underlying conductive features such as metal pads are exposed. The openings are then filled with conductive materials. A planarization process may performed to remove excess portions of the conductive materials higher than the top surface of dielectric layer 44. Alternatively, electrical connectors 42 may be formed as metal pillars protruding higher than the top surface of dielectric layer 44. The respective formation process may include plating.

Throughout the description, the side of substrate 34 having the integrated circuit devices formed is referred to as the front side of substrate 34. Accordingly, the illustrated top side of substrate 34 and wafer 32 is referred to as the front side of substrate 34 and wafer 32, respectively. The side (the illustrated bottom side) of substrate 34 and wafer 32 opposite to the front side is referred to the backside.

Wafer 32 is then flipped upside down, as shown in FIG. 3. The front side (the top side as shown in FIG. 2) of wafer 32 is attached to carrier 50 through release film 52. The respective process is illustrated as process 206 in the process flow 200 as shown in FIG. 32. Carrier 50 may be a glass carrier, a silicon wafer, an organic carrier, or the like. Release film 52 may be formed of a polymer-based material (such as a Light-To-Heat-Conversion (LTHC) material). The release film 52 is capable of being decomposed under radiation such as a laser beam, so that carrier 50 may be de-bonded from the overlying structures that will be formed in subsequent processes.

Next, a backside grinding process is performed on semiconductor substrate 34. The respective process is illustrated as process 208 in the process flow 200 as shown in FIG. 32. The backside grinding process is performed until through-vias 36 are exposed. The resulting wafer 32 is shown in FIG. 3. In accordance with some embodiments, after through-vias 36 are exposed, semiconductor substrate 34 is slightly recessed, for example, through an etching process, so that the top portions of through-vias 36 protrude out of the recessed semiconductor substrate 34.

Next, a dielectric isolation layer (not shown) is formed to embed the protruding portions of through-vias 36 therein. The dielectric isolation layer is then formed by depositing a dielectric material, which may be formed of or comprise silicon oxide, silicon nitride, or the like. A planarization process is then performed to remove the excess portions of the dielectric material over through-vias 36, so that through-vias 36 are revealed.

Backside interconnect structure 54 is then formed. The respective process is illustrated as process 210 in the process flow 200 as shown in FIG. 32. Backside interconnect structure 54 may include RDLs 58 and dielectric layers 56. RDLs 58 may be formed of or comprise copper, aluminum, nickel, titanium, or the like, or multi-layers thereof. Each of dielectric layers 56 may be formed of or comprise an inorganic material(s) and/or an organic material(s). The inorganic materials may include silicon nitride, silicon oxide, silicon carbide, silicon oxynitride, silicon oxy-carbo-nitride, or the like, combinations thereof, and/or multi-layers thereof. The organic materials may include polyamide, PBO, or the like.

Electrical connectors 62 and polymer layer 64 are then formed. The respective process is illustrated as process 212 in the process flow 200 as shown in FIG. 32. Electrical connectors 62 are formed at the top surface of wafer 32, and are electrically connected to through-vias 36. In accordance with some embodiments, electrical connectors 62 comprise non-solder conductive features 62A (such as metal bumps), which may be formed of copper, nickel, palladium, gold, or the like, combinations thereof, and/or multi-layers thereof. There may be, or may not be, solder layers 62B over the non-solder conductive features 62A. The solder layers 62B may be formed of a lead-free solder.

Polymer layer 64 is formed to encapsulate at least the lower parts, or the entireties of, electrical connectors 62. In accordance with some embodiments, polymer layer 64 is formed of or comprises polyimide, PBO, BCB, or the like. The details of the materials, the structures, and the formation process of electrical connectors 62 are discussed in detail referring to FIGS. 11 through 22.

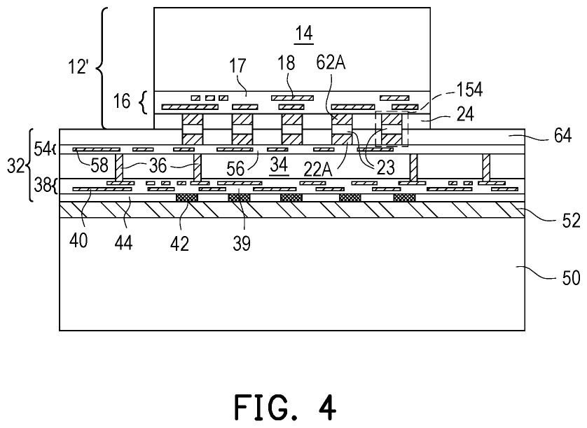

Referring to FIG. 4, device dies 12′ are bonded to device dies 32′ in wafer 32. The respective process is illustrated as process 214 in the process flow 200 as shown in FIG. 32. Through-vias 36 are thus electrically connected to the integrated circuit devices in device dies 12′. The bonding is performed through face-to-back bonding, wherein the front side of device dies 12′ faces the backside of wafer 32 Although face-to-back bonding is used as an example, the embodiments may be applied to face-to-face bonding and back-to-back bonding also. Although one device die 12′ is illustrated, there may be a plurality of device dies 12′ bonding to wafer 32. The bonding of device dies 12′ to wafer 32 may be achieved through polymer hybrid bonding, which includes the bonding of electrical connectors 22 to electrical connectors 62, and polymer layer 24 to polymer layer 64. Solder regions 23 may be, or may not be, formed. The details of the bonding process and the resulting structure are discussed in detail referring to FIGS. 11 through 22.

In accordance with some embodiments, after the bonding process, a backside grinding process is performed to thin device dies 12′. Through the thinning of device dies 12′, the aspect ratio of the gaps between neighboring device dies 12′ is reduced in order to reduce the difficulty in the subsequent gap-filling process.

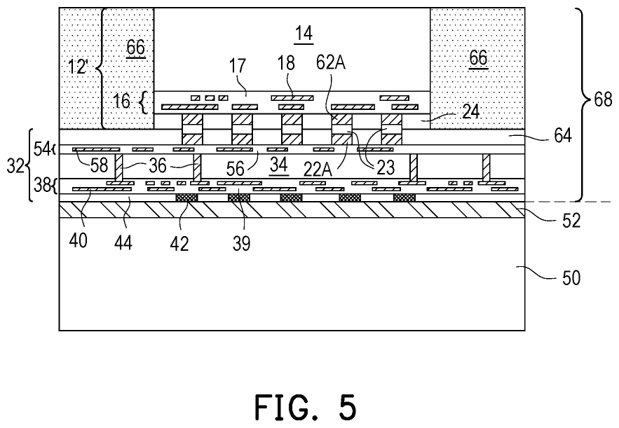

FIG. 5 illustrates the formation of gap-filling materials/layers 66, which encapsulates device dies 12′. The respective process is illustrated as process 216 in the process flow 200 as shown in FIG. 32. In accordance with some embodiments, the gap-filling materials/layers include a dielectric liner and a dielectric layer. The dielectric liner is formed of a dielectric material that has good adhesion to the sidewalls of device dies 12′ and the top surface of polymer layer 64. In accordance with some embodiments, the dielectric liner is formed of a nitride-containing material such as silicon nitride. The dielectric liner may be a conformal layer. The formation of the dielectric liner may include a conformal deposition process such as ALD, CVD, or the like.

The dielectric layer is formed of a material different from the material of the dielectric liner. In accordance with some embodiments, the dielectric layer may be formed of silicon oxide, while other dielectric materials such as silicon carbide, silicon oxynitride, silicon oxy-carbo-nitride, Phospho silicate glass (PSG), Boron-doped Silicate Glass (BSG), Boron-doped Phospho silicate glass (BPSG), or the like may also be used. The dielectric layer may be formed using CVD, High-Density Plasma Chemical Vapor Deposition (HDPCVD), Flowable CVD, spin-on coating, or the like. The dielectric layer fully fills the gaps between device dies 12′.

In accordance with alternative embodiments of the present disclosure, instead of forming the dielectric liner and the dielectric layer, device die 12′ are encapsulated by a polymer-based encapsulant, which may include or may be formed of molding compound, molding underfill, a resin, an epoxy, and/or the like.

Next, a planarization process such as a CMP process or a mechanical grinding process is performed to remove excess portions of gap-filling layers 66, so that device dies 12′ are exposed. The remaining portions of gap-filling layers 66 are collectively referred to as (gap-filling) isolation regions 66. Throughout the description, wafer 32 and the overlying device dies 12′ are collectively referred to as reconstructed wafer 68.

Reconstructed wafer 68 is then de-bonded from carrier 50. The respective process is illustrated as process 218 in the process flow 200 as shown in FIG. 32. In the de-bonding process, a light beam (which may be a laser beam) may be projected on release film 52, and the light beam penetrates through the transparent carrier 50. Release film 52 is thus decomposed. Carrier 50 may be lifted off from release film 52, and hence reconstructed wafer 68 is de-bonded (demounted) from carrier 50.

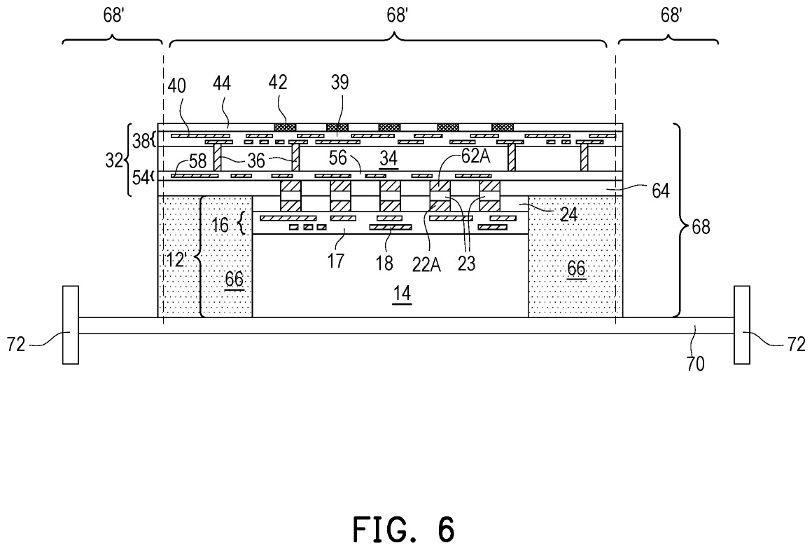

Referring to FIG. 6, reconstructed wafer 68 is placed on dicing tape 70, which is further fixed on frame 72. A singulation process is then performed to saw reconstructed wafer 68 into a plurality of identical packages 68′. The respective process is illustrated as process 220 in the process flow 200 as shown in FIG. 32.

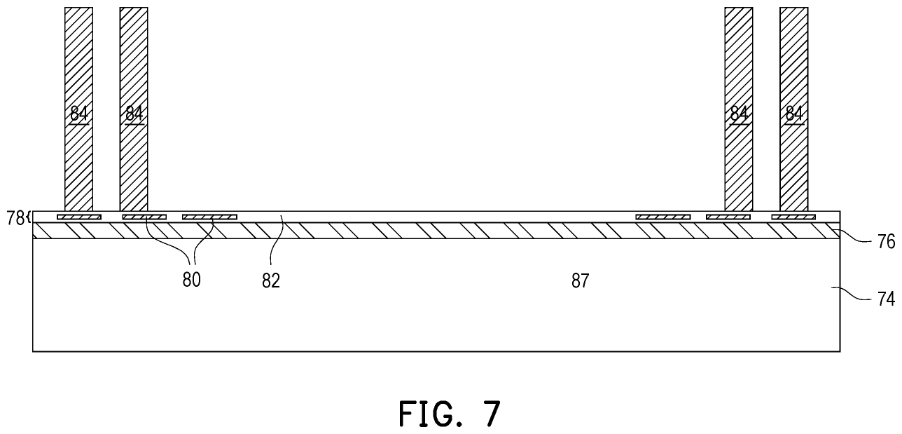

FIGS. 7 through 9 illustrate the packaging of packages 68′ in accordance with some embodiments. Referring to FIG. 7, carrier 74 and release film 76 are provided. Carrier 74 may be a glass carrier, and release film 76 may be a LTHC film in accordance with some embodiments. Redistribution structure 78 is formed on release film 76. The respective process is illustrated as process 222 in the process flow 200 as shown in FIG. 32. In accordance with some embodiments, redistribution structure 78 includes dielectric layers 82 and RDLs 80 therein. Dielectric layers 82 may be formed of or comprise polymers such as PBO, polyimide, BCB, or the like.

Metal posts 84 are formed over redistribution structure 78, and are electrically connected to RDLs 80. The respective process is illustrated as process 224 in the process flow 200 as shown in FIG. 32. The formation process may include etching the top dielectric layer in dielectric layers 82 to expose some of RDLs 80, depositing a metal seed layer, forming a patterned plating mask, plating the metal posts 84, and removing the patterned plating mask. The portions of the metal seed layer not directly under the plated metal posts 84 are then removed through etching.

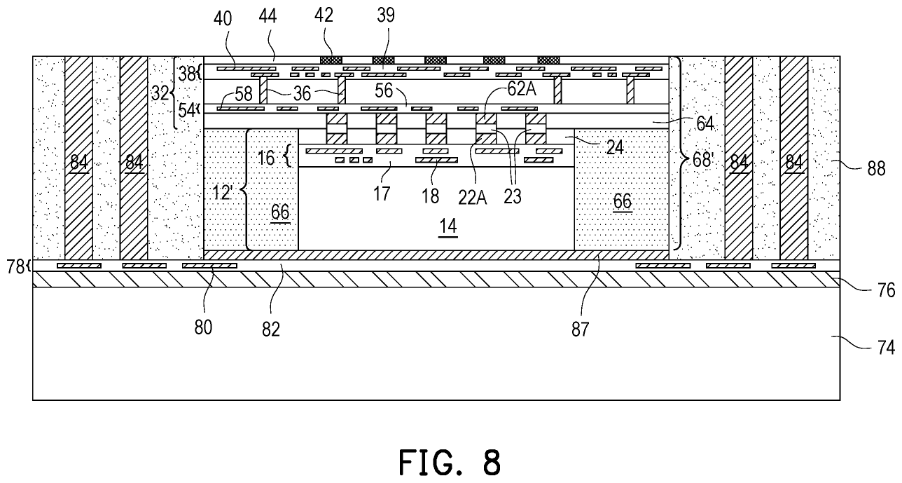

Next, referring to FIG. 8, packages 86′ are placed on interconnect structure 78 through die-attach films 87. The respective process is illustrated as process 226 in the process flow 200 as shown in FIG. 32. Encapsulant 88 is then dispensed to encapsulate packages 86′ and metal posts 84. The respective process is illustrated as process 228 in the process flow 200 as shown in FIG. 32. Encapsulant 88 may include a molding compound, a molding underfill, an epoxy, and/or a resin, or may include an inorganic dielectric material(s) such as silicon nitride, silicon oxide, and the like. Encapsulant 88 may include a base material, and a filler in the base material. The base material may include a polymer. The filler may include titanium dioxide, carbon black, calcium carbonate, silica, fiber, clay, ceramic, inorganic particles, and or the like, and may be in the form of filler particles.

A planarization process such as a CMP process or a mechanical grinding process is then performed to polish encapsulant 88. Electrical connectors 42, dielectric layer 44, and through-vias 84 are thus exposed. Metal posts 84 are referred to as through-vias 84 hereinafter.

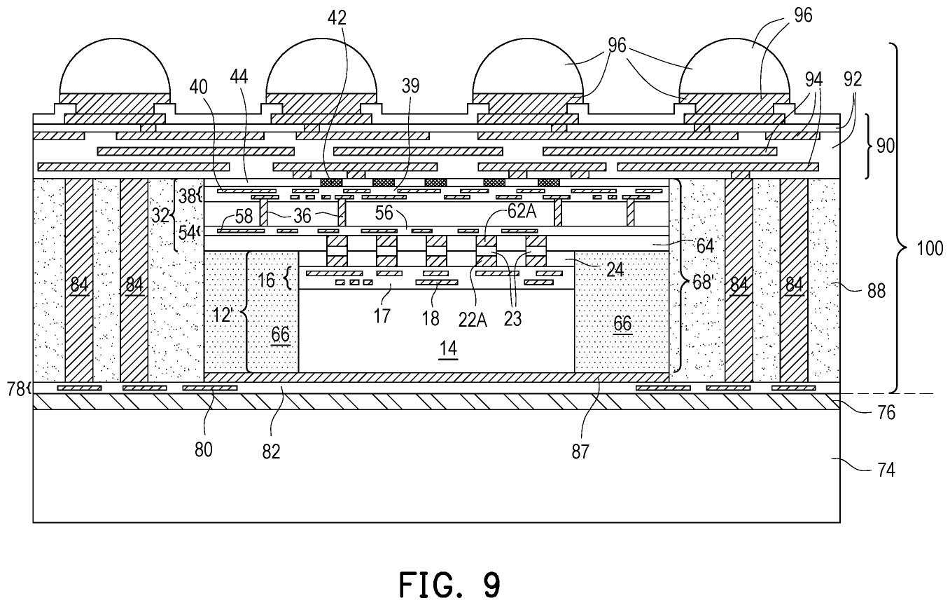

Next, referring to FIG. 9, redistribution structure 90 is formed over and electrically coupling to electrical connectors 42 and through-vias 84. The respective process is illustrated as process 230 in the process flow 200 as shown in FIG. 32. In accordance with some embodiments, redistribution structure 90 includes dielectric layers 92 and RDLs 94 therein. Dielectric layers 92 may be formed of or comprise polymers such as PBO, polyimide, BCB, or the like. Electrical connectors 96, which may comprise metal pads, metal pillars, solder regions, or the like, or combinations, are then formed over and electrically connecting to RDLs 94. The portions of the structure over release film 76 is referred to as reconstructed wafer 100 hereinafter.

The reconstructed wafer 100 is then de-bonded from carrier 74, followed by a sawing process, so that identical packages 100′ in the reconstructed wafer 100 are separated from each other. The respective process is illustrated as process 232 in the process flow 200 as shown in FIG. 32. One of the packages 100′ in the reconstructed wafer 100 is shown in FIG. 10. Package 100′ is bonded to package 102 in accordance with some embodiments, for example, through solder regions 104 to form package 101. The respective process is illustrated as process 234 in the process flow 200 as shown in FIG. 32.

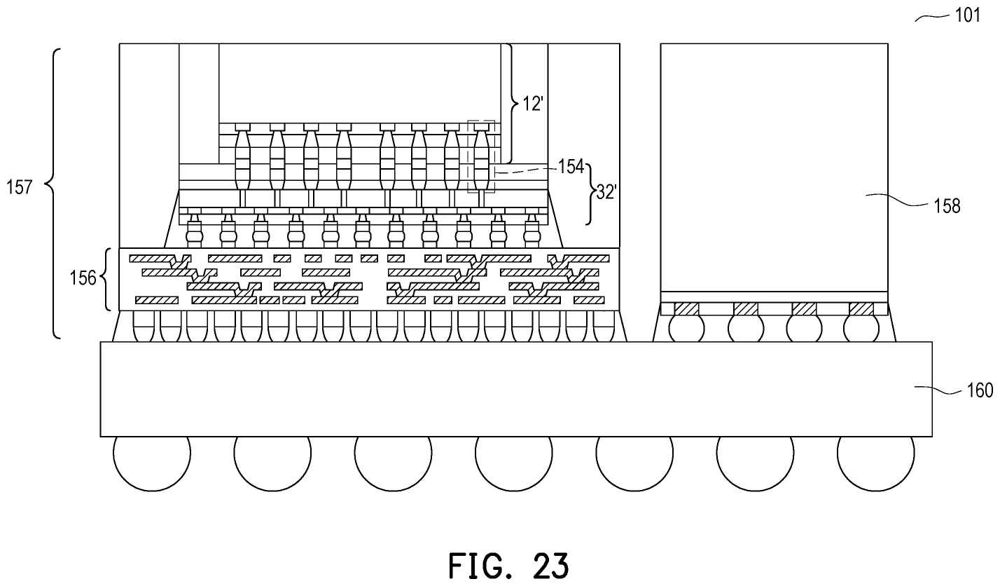

FIGS. 11 through 22 illustrate the bonding process of two package components 120 and 140 through polymer hybrid bonding in accordance with some embodiments. Each of the bonded packages components 120 and 140 may represent one of device dies 12′ and wafer 32 in FIG. 4, or may represent the package components illustrated in FIGS. 23 through 31, as will be discussed in subsequent paragraphs. In accordance with some embodiments, the bonded structures 154 as shown in FIGS. 14, 18, and 22 may represent the bond structure 154 shown in FIG. 4.

Referring to FIG. 11, package components 120 and 140 are formed. Each of package components 120 and 140 may be a device die, a device wafer, an interposer die, an interposer wafer, a package, or the like. In accordance with some embodiments, package component 120 comprises surface dielectric layer 122, metal pad 124, via 126, and electrical connector 128 protruding out of surface dielectric layer 122. Electrical connector 128 may comprise a non-solder metal pillar 128A, and a solder region 128B on non-solder metal pillar 128A. Package component 140 may comprise surface dielectric layer 142, metal pad 144, via 146, and electrical connector 148 protruding out of surface dielectric layer 142.

Electrical connector 148 is also formed of a non-solder metallic material, and may or may not include a solder region. Electrical connector 148 and non-solder metal pillar 128A may be formed of or comprise copper in accordance with some embodiments. The solder region such as solder region 128B may be lead-free, and may comprise SnAg, for example.

In accordance with some embodiments, electrical connector 128 has width W1 in the range between about 4 μm and about 8 μm. Non-solder metal pillar 128A has height H1, which may be in the range between about 3 μm and about 7 μm. Solder region 128B has height H2, which may be in the range between about 5 μm and about 10 μm. Electrical connector 148 has width W2, which may be equal to, greater than, or smaller than width W1. Height H3 of electrical connector 148 may be in the range between about 10 μm and about 18 μm.

Referring to FIG. 12, polymer layers 130 and 150 are formed. Each of the polymer layers 130 and 150 may represent the polymer layer 24 or 64 in FIG. 10 in accordance with some example embodiments. Each of polymer layers 130 and 150 may be formed of or comprises a polymer such as polyimide, PBO, BCB, or the like. Each of polymer layers 130 and 150 may also be formed of a non-conductive film (NCF), which is pre-formed as a solid layer that is laminated on the corresponding electrical connectors 128 and 148. Each of polymer layers 130 and 150 may also be formed of a non-conductive paste (NCP), which is dispensed in a flowable form, and then cured as a solid layer. The NCF and NCP may use epoxy resin as base materials, and filler particles may be added as fillers to reduce the coefficient of thermal expansion. Each of the polymer layers 130 and 150 may be formed of a homogeneous material free from filler particles therein, or may comprise a polymer and filler particles.

In accordance with some embodiments, polymer layer 130 is recessed to form recess 131. The formation process may include dispensing polymer layer 130 to cover electrical connector 128, curing polymer layer 130, performing a planarization process to level the surface of polymer layer 130, and removing the portion of polymer layer 130 covering electrical connector 128. The removal of the portion of polymer layer 130 may include a light-exposure process and a development process when polymer layer 130 is formed of a photo-sensitive material such as polyimide, PBO, or the like. Otherwise, the portion of polymer layer 130 may be removed by forming a patterned photoresist, and etching the undesirable portion of the polymer layer 130 using the patterned photoresist to define patterns. In accordance with some embodiments, recess 131 has depth D1 in the range between about 0.2 μm and about 1 μm.

In accordance with some embodiments, the edges (sidewalls) 130SW1 of polymer layer 130 are vertically aligned with the edges of electrical connector 128. In accordance with alternative embodiments, polymer layer 130 has edges 130SW2 (as represented by dashed lines), which are overlapped by electrical connector 128. In accordance with yet alternative embodiments, polymer layer 130 has edges 130SW3 (as represented by dashed lines), which are spaced apart from the respective edges of electrical connector 128. There may thus be voids 135 between polymer layer 130 and electrical connector 128. Since the edges of polymer layer 130 forms a ring (when viewed from bottom), polymer layer 130 may be considered as comprising multiple edges (which are connected to form the ring). Accordingly, edges 130SW1, 130SW2, and 130SW3 may exist for the same electrical connector 128 in any combination. Also, for different electrical connectors 128 of the same device die, edges 130SW1, 130SW2, and 130SW3 may exist in any combination.

In accordance with some embodiments, electrical connector 148 includes a top portion protruding out of polymer layer 150. The formation process may include dispensing polymer layer 150 to cover electrical connector 148, and curing polymer layer 150. A planarization process is then performed to level the surface of polymer layer 150. Polymer layer 150 is then etched back. In accordance with some embodiments, the protruding portion of electrical connector 140 has height H4 in the range between about 0.2 μm and about 1 μm.

Having one of electrical connectors being protruding, and the other being recessing has the advantageous feature of self-aligning package components 120 and 140. In accordance with alternative embodiments, electrical connector 128 and polymer layer 130 have their corresponding surfaces coplanar with each other, and electrical connector 148 and polymer layer 150 have their corresponding surfaces coplanar with each other. This embodiment has reduced manufacturing cost.

In accordance with some embodiments, polymer layers 130 and 150 are partially cured before the they are planarized. A parameter “imidization ratio” may be used to measure the degree of curing. The higher the imidization ratio, the higher the mechanical strength the polymer material will have, and the corresponding polymer layer 130 and 150 are harder. The imidization ratio of polymers 130 and 150, after being partially cured, may be in the range between about 35 and about 95. The partial curing process may be achieved by controlling the temperature and curing time. In accordance with some embodiments, the partial curing process may be performed at a first temperature in the range between about 160° C. and about 190° C. The curing time may be in the range between about 10 seconds and about 200 seconds. Also, the curing temperature may be lower than the melting/reflowing temperature of solder region 128B, so that solder regions 128B may maintain their shapes during the curing.

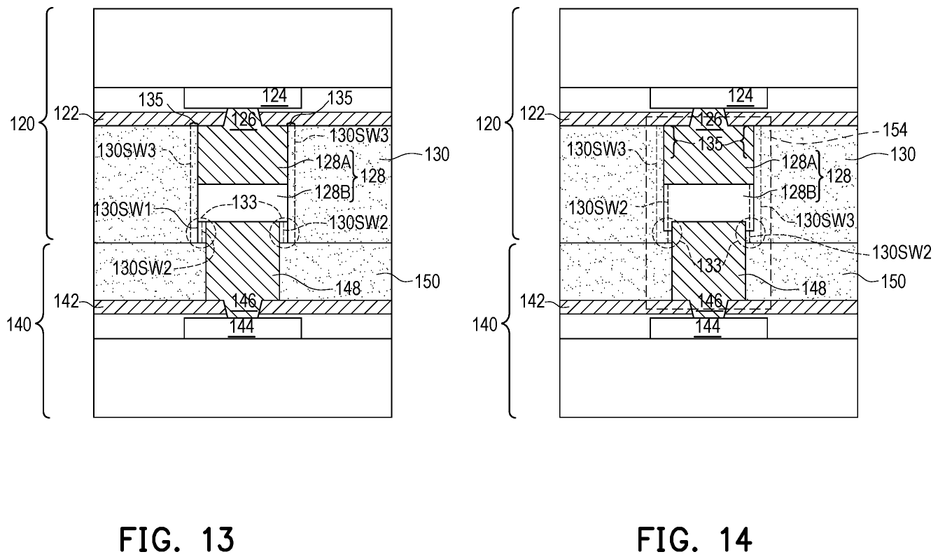

Next, as shown in FIG. 13, package components 120 and 140 are picked up and placed against each other. Electrical connectors 128 and 148 are in contact with each other. In accordance with some embodiments, voids 133 may exist between the sidewalls of electrical connector 148 and the nearest sidewalls of polymer layer 130. When polymer layer 130 has sidewall 130SW3, voids 135 also exists, and may be joined with voids 133.

A Thermal Compression Bonding (TCB) process is then performed, in which package components 120 and 140 are pressed against each other, and heating is simultaneously performed. In accordance with some embodiments, the bonding process includes pre-heating package components 120 and 140 for polymer bond, wherein the pre-heating process includes heating package components 120 and 140 to a second temperature in the range between about 150° C. and about 200° C., and for a period of time in the range between about 1 second and about 20 seconds. The pre-heating may be started before the compression of package components 120 and 140. The second temperature may also be lower than the melting/reflowing temperature of solder region 128B.

After the pre-heating process, package components 120 and 140 are heated to a third temperature higher than the second temperature, so that solder region 128B is reflowed to join non-solder metal pillar 128A with electrical connector 148. The resulting structure is shown in FIG. 14. The reflow process may be performed at a third temperature in the range between about 250° C. and about 300° C., for a period of time in the range between about 10 second and about 60 seconds. In the reflow process, the area of solder region 128B may be defined by the corresponding surfaces and edges of polymer layers 130 and 150. The edges of solder region 128B may be straight and vertical, which edges may interface with sidewalls 130SW1, 130SW2, and/or 130SW3 of polymer layer 130, depending on which sidewalls may be formed in preceding processes.

In accordance with some embodiments, when polymer layer 130 has edges 130SW2, some portions of polymer layers 130 and 150 may be squeezed into voids 133 to fill the voids. Regions 133 are thus filled with the polymer(s) from polymer layers 130 and/or 150. In accordance with alternative embodiments when polymer layer 130 has voids 135, polymer layer 130 may or may not be squeezed into some parts of voids 135 to fill these regions. Accordingly, there may also be some voids 135 remaining after the bonding of polymer layers 130 and 150.

After the reflow process, an annealing process may be performed to fully cure polymer layers 130 and 150. In accordance with some embodiments, the annealing process may be performed at a fourth temperature in the range between about 200° C. and about 300° C., and for a period of time in the range between about 0.5 hours and about 3 hours. During the annealing process, the compression force may remain to be applied to press polymers 130 and 150 against each other, so that better polymer bonding may be formed. Alternatively, in then annealing process, the compression force may be removed.

Due to the annealing process, polymer layers 130 and 150 are fully cured, and have second imidization ratios, which are higher than the first imidization ratios of polymer layers 130 and 150. In accordance with some embodiments, the second imidization ratios are in the range between about 95 and about 100. A bond structure 154 is thus formed. The bond structure is also shown in FIG. 4 in accordance with some embodiments. In the bond structure 154, The edges of polymer layer 130 may be 130SW1, 130SW2, and/or 130SW3. The sidewalls of solder regions in the bond structures 154, if any, may be straight and vertical, and may be defined by edges 130SW1, 130SW2, and/or 130SW3.

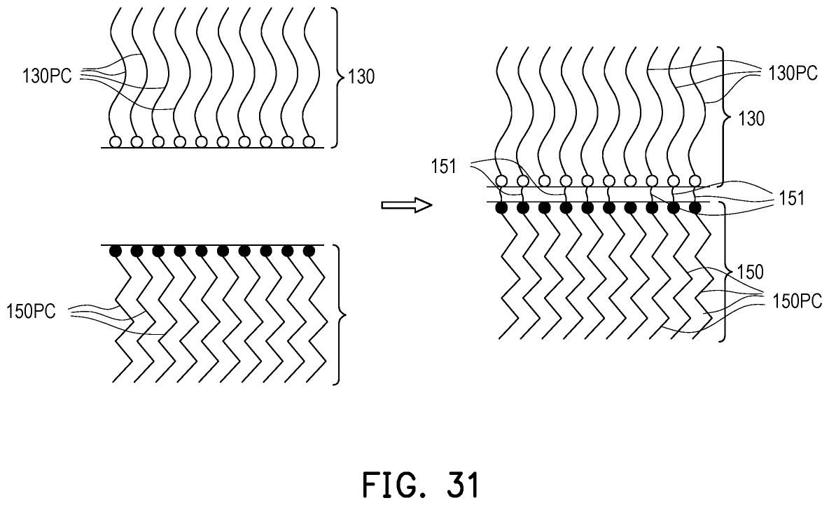

Also, due to the thermal compression bond process and the annealing process, polymer layers 130 and 150 may form bonds therebetween, wherein hydrogen bonds and covalent bonds are formed to bond polymer layers 130 and 150 together. FIG. 31 schematically illustrates the bonding of polymer layers 130 and 150. After the polymer bonding of polymer layers 130 and 150, long chain polymers may be formed. The long chain polymers may include polymer chains 130PC in polymer layer 130 and polymer chains 150PC in polymer layer 150. Due to the polymer bonding, polymer chains 130PC are joined to polymer chains 150PC through polymer bonds 151 to form longer polymer chains, which extend from first positions inside polymer layer 130 to second positions inside polymer layer 150.

When polymer layers 130 and 150 are formed of the same polymer, the interface between the polymer layers 130 and 150 may be distinguishable or not distinguishable. Regardless of whether the polymer materials of polymer layers 130 and 150 are the same or different from each other, bonding/crosslinking between the polymer chains will occur due to the polymer bonding. The bonding strength may be different depending on the choice of materials.

It is appreciated that depending on the materials of polymer layers 130 and 150, the process conditions for bonding may vary, with some polymer materials requiring longer time and/or higher temperatures than other polymer materials to bond and form long polymer chains. Also, adequate compression force is needed to form the polymer bonds. Experiments may thus be performed to find the process conditions to bond specific polymer materials that are selected.

Referring again to FIG. 14, in accordance with some embodiments, the bonding of package components 120 and 140 include metal bonds (such as solder bonds, metal-to-metal direct bonds, etc.) and polymer bonds, which collectively form polymer hybrid bond structure 154.

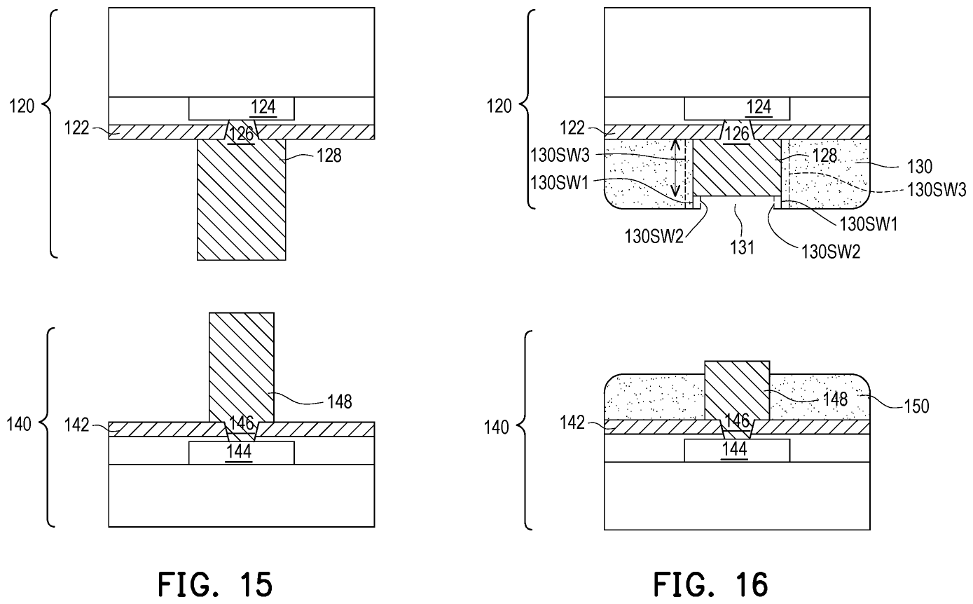

FIGS. 15 through 18 illustrate the polymer hybrid bond structure 154 formed in accordance with alternative embodiments. These embodiments are similar to the embodiments as shown in FIGS. 11 through 14, except that the bonding of electrical connectors is through metal-to-metal direct bonding rather than solder bonding.

Referring to FIG. 15, package components 120 and 140 are formed, with electrical connectors 128 and 148 being protruding out of the respective dielectric layers 122 and 142, respectively. Electrical connectors 128 and 148 do not include solder, and are formed of non-solder metallic materials such as copper.

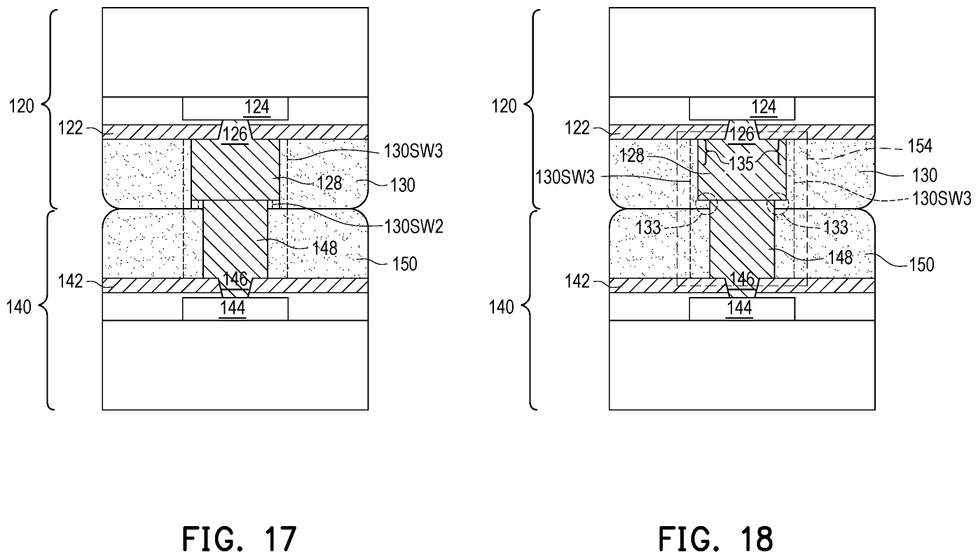

Referring to FIG. 16, polymer layers 130 and 150 are formed. The details are similar to what are discussed referring to FIG. 12, and are not repeated herein. FIG. 17 illustrates the placement of package components 120 and 140, and the pre-heating process, which are essentially the same as discussed referring to FIG. 13.

Since no solder is in electrical connectors 128 and 148, after the pre-heating process, no reflow process is performed. Instead, a heating process to achieve the direct metal-to-metal bonding of electrical connectors 128 and 148. The heating process may be performed at a higher temperature (higher than the pre-heating temperature) in the range between about 300° C. and about 400° C., for a period of time in the range between about 120 second and about 360 seconds.

FIG. 18 illustrates the annealing process to improve the metal-to-metal direct bonding between connectors 128 and 148, wherein inter-diffusion of the metals such as copper is achieved to bond electrical connectors 128 and 148. In addition, polymers 130 and 150 are also bonded to each other through polymer bonding, for example, with long polymer chains being formed extending from the positions from inside polymer layer 130 into the positions inside polymer layer 150. The annealing process may be performed using same process conditions as that discussed referring to FIG. 14, and is not repeated herein. Polymer hybrid bond structure 154 is thus formed.

In hybrid bond structure 154, regions 133 may be voids, or may be filled with the squeezed polymer layers 130 and/or 150. Also, regions 135 may be polymer regions or may be voids.

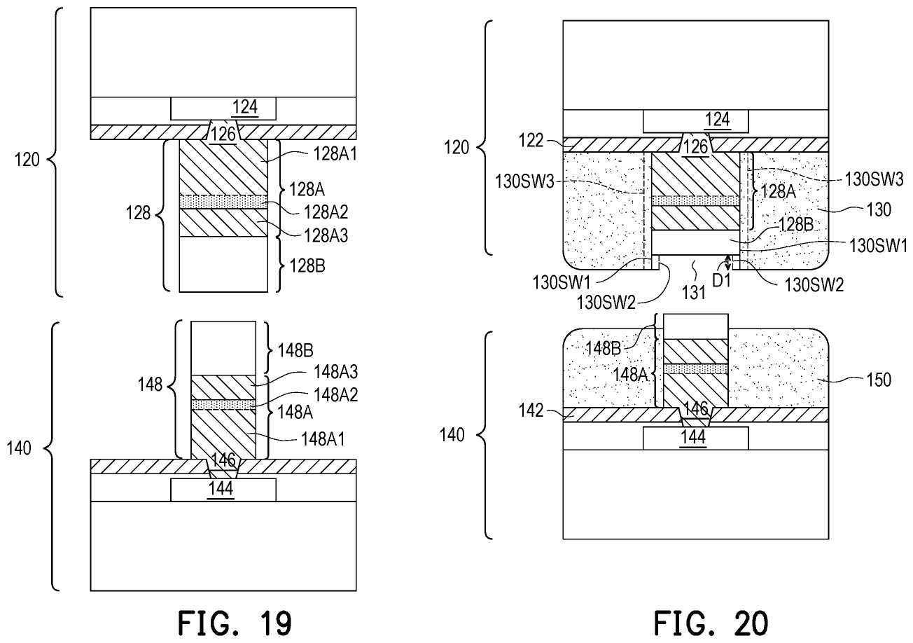

FIGS. 19 through 22 illustrate the polymer hybrid bond structure 154 formed in accordance with alternative embodiments. These embodiments are similar to the embodiments as shown in FIGS. 11 through 14, except that solder regions may be formed on both of the bonded electrical connectors.

Referring to FIG. 19, package components 120 and 140 are formed, with electrical connectors 128 and 148 being protruding out of the respective dielectric layers 122 and 142, respectively. Electrical connector 128 includes non-solder metal pillar 128A and solder layer 128B. Electrical connector 148 includes non-solder metal pillar 148A and solder layer 148B.

In addition, FIG. 19 also illustrates that one or each of the electrical connectors 128 and 148 may include a single non-solder metal layer or a plurality of sub metal layers. For example, non-solder metal pillar 128A may include a copper layer 128A1 and a nickel layer 128A2, and metal layer 148A may include a copper layer 148A1 and a nickel layer 148A2. There may be, or may not be, an additional copper layer 128A3 between nickel layer 128A2 and solder layer 128B. There may be, or may not be, an additional copper layer 148A3 between nickel layer 148A2 and solder layer 148B. It is appreciated that the discussed copper and nickel layers are examples, and the non-solder metal pillars 128A and 128B may include any other applicable material and layers.

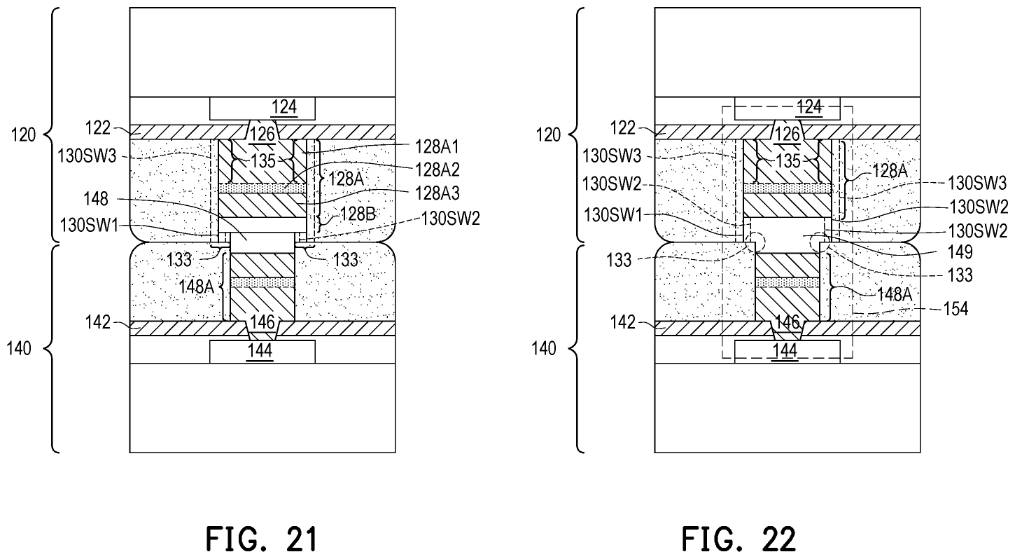

Referring to FIG. 20, polymer layers 130 and 150 are formed. The details are similar to what are discussed referring to FIG. 12, and are not repeated herein. FIG. 21 illustrates the picking and placing of package components 120 and 140, and the pre-heating process, which are essentially the same as discussed referring to FIG. 13. Voids 133 may be formed. The reflow process results in the melting of both of solder regions 128B and 148B to form solder region 149, as shown in FIG. 22.

FIG. 22 further illustrates the annealing process to bond polymers 130 and 150 to each other, for example, with long polymer chains being formed extending from inside polymer layer 130 into polymer layer 150. The annealing process may be performed using same process conditions as that discussed referring to FIG. 14, and is not repeated herein. Voids 133 and/or 135 may be formed. Alternatively, the regions of 133 and/or 135 may be filled with polymer layers due to the compression.

In the bond structure 154 as shown in FIGS. 14, 18, and 22, the shapes and the volumes of some features are defined by the edges of the polymer layers 130 and 150. The volume and the shapes of solder regions are also defined by polymer layers 130 and 150, which are pre-formed to have the desirable shape. The bridging of solder regions is thus reduced. The bond strength is also improved due to the additional bonding of polymer layers.

FIGS. 23 through 30 illustrate some example packages 101 in which the polymer hybrid bonding process may be used. It is appreciated that these structures are examples, and the polymer hybrid bonding may be used on any other structures whenever applicable.

FIG. 23 illustrates an Integrated Fan-Out (InFO) package 157, which includes device die 12′ bonding to interposer die 32′. Fan-out redistribution structure 156 is bonded to the overlying structure to form fan-out package 157, with the RDLs in the fan-out redistribution structure 156 laterally extending beyond (fan-out) the edges of the overlying structure. Memory stack 158 is also formed, with both of the fan-out package 157 and the memory stack 158 being bonding to package substrate 160. The polymer hybrid bond structure 154 may be formed to include the bonded portions of device die 12′ and interposer die 32′.

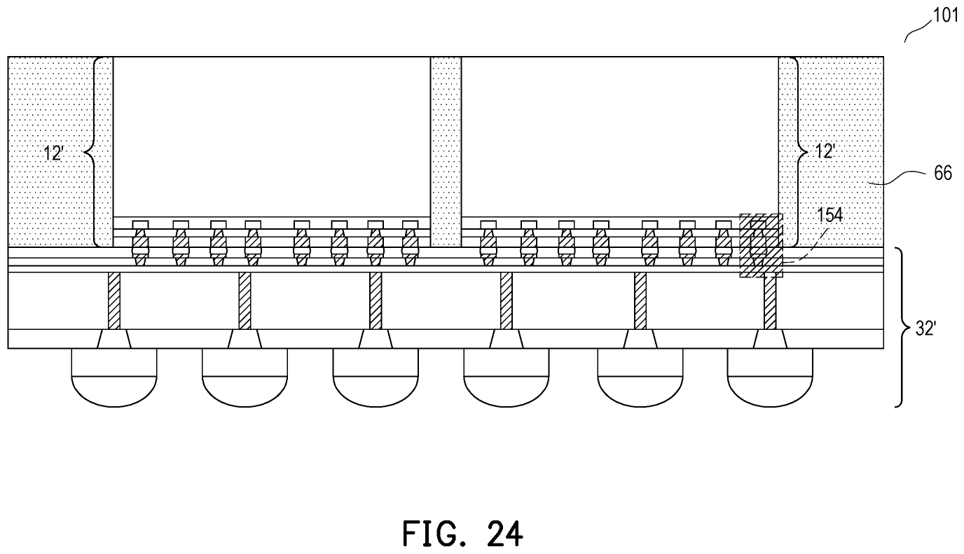

FIG. 24 illustrates a package 101 in which package components 12′ (such as device dies and/or SoC dies) are bonded to interposer die 32′. Package components 12′ may be encapsulated in encapsulant 66. The polymer hybrid bond structure 154 may be formed to bond device die 12′ to interposer die 32′.

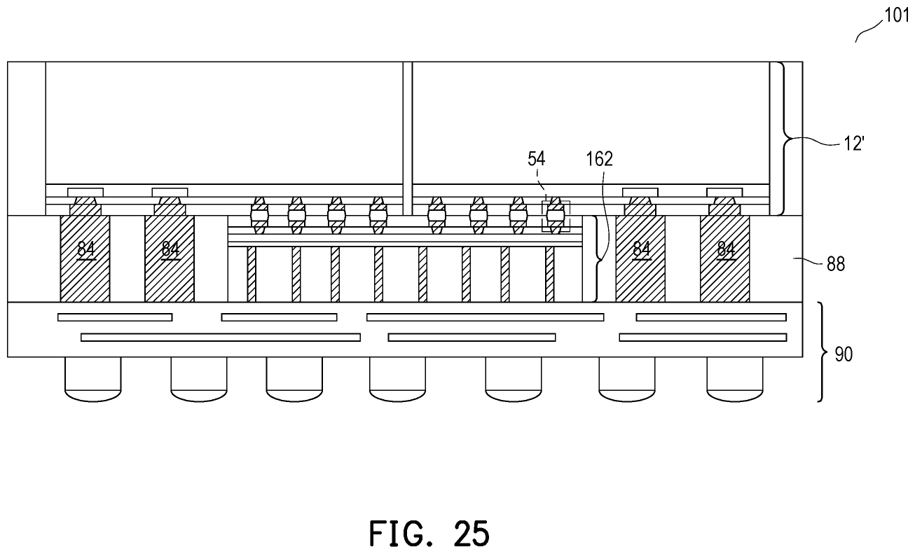

FIG. 25 illustrates package 101, which includes device die 12′ bonding to Local Silicon Interconnect (LSI) interposer die 162 with face-to-face bonding. LSI interposer die 162 is used for bridging device dies 12′, and is also used to connect device dies 12′ to the underlying interconnect structure 90. The polymer hybrid bond structure 154 may be formed to bond device die 12′ to LSI interposer die 162.

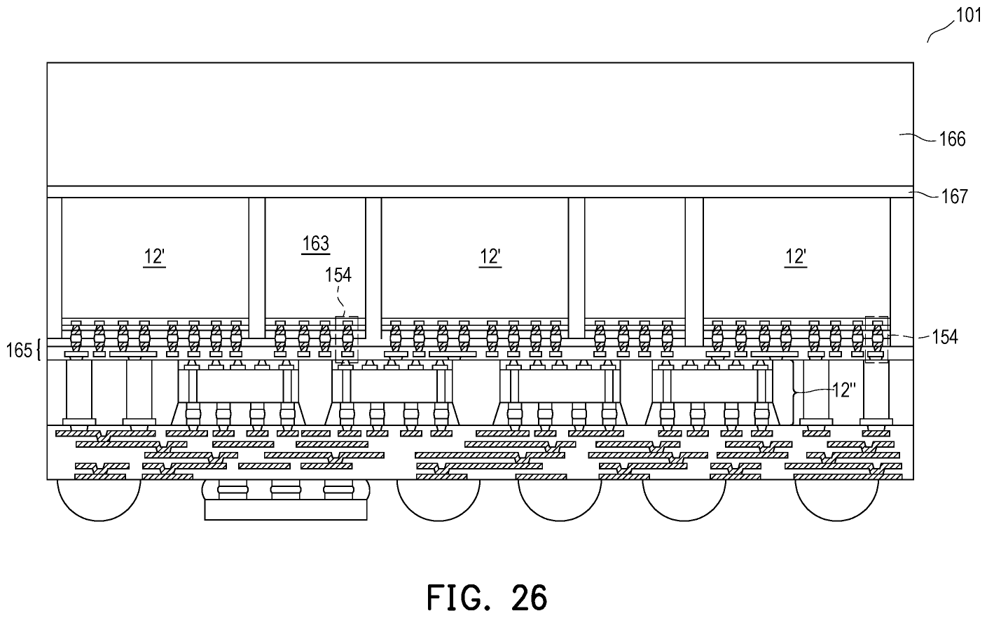

FIG. 26 illustrates package 101, which includes package components 12′ and bridge dies 163 bonding to an interconnect structure 165, which are further bonded to package components 12″. Package components 12″ may include through-vias therein, and may be used for bridging package components 12′. A heat sink such as a blank silicon substrate 166 is bonded to the underlying structure, for example, through thermal interface material 167. The polymer hybrid bond structure 154 may be formed to bond package components 12′ and bridge dies 163 to interconnect structure 165. The polymer hybrid bond structure 154 may also be formed to bond package components 12″ to bridge dies 163.

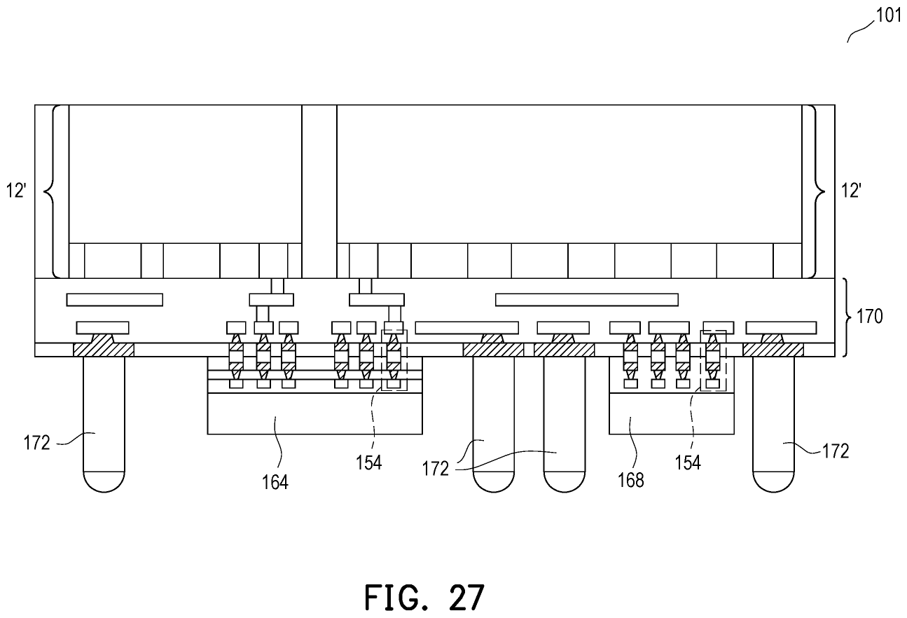

FIG. 27 illustrates a package 101 including package components 12′ bonding to an interconnect structure 170. LSI die 164 and Independent Passive Device (IPD) die 168 are also bonded to interconnect structure 170. LSI die 164 may interconnect package components 12′. Metal posts 172 are formed to extend below the bottoms of LSI die 164 and IPD die 168. The polymer hybrid bond structure 154 may be formed to bond LSI die 164 and IPD die 168 to interconnect structure 170.

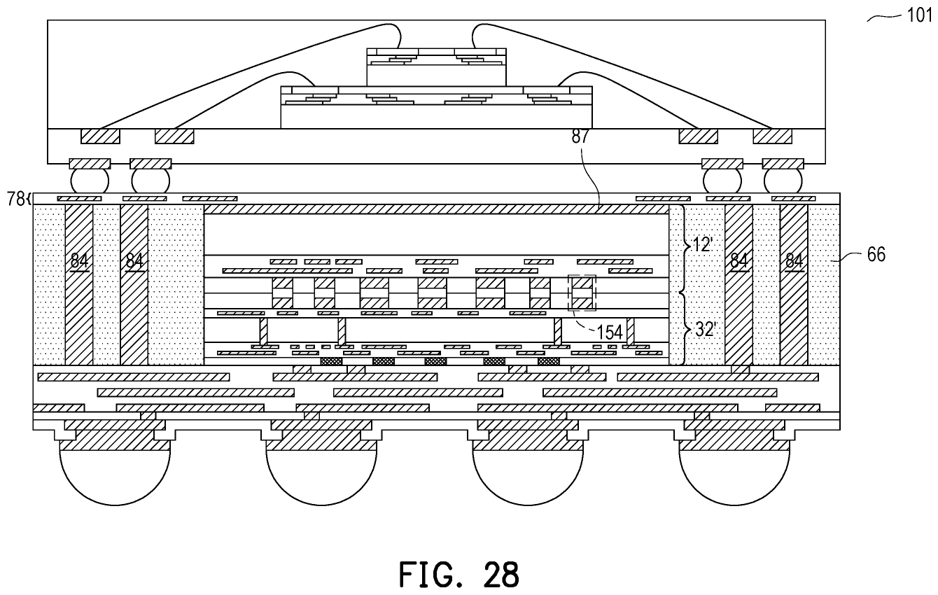

FIG. 28 illustrates a package 101 similar to the package shown in FIG. 10, except that interposer die 32′ and package component 12′ have the same width. The polymer hybrid bond structure 154 may be formed to bond device die 12′ to interposer 32′.

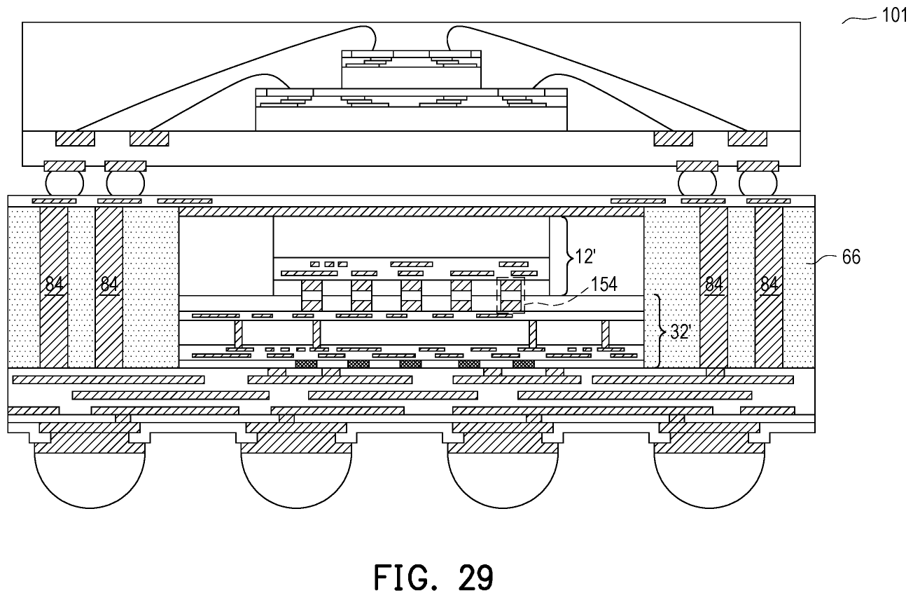

FIG. 29 illustrates a package 101 similar to the package shown in FIG. 28, except that interposer die 32′ is wider than package component 12′. The polymer hybrid bond structure 154 may be formed to bond device die 12′ to interposer 32′.

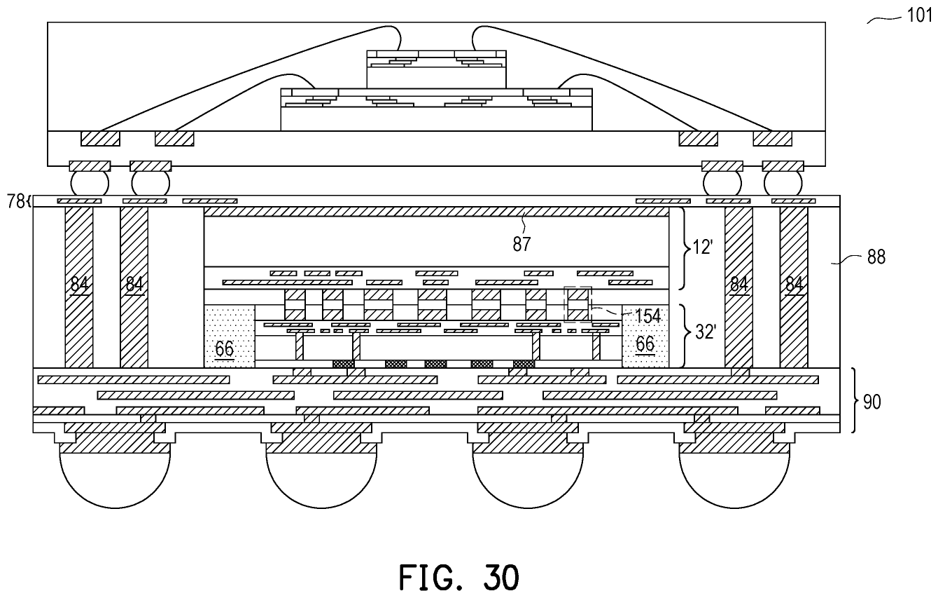

FIG. 30 illustrates a package similar to the package shown in FIG. 10, except that interposer die 32′, rather than package component 12′ is encapsulated in encapsulant 66. Interposer die 32′ is narrower than package component 12′. The polymer hybrid bond structure 154 may be formed to bond device die 12′ and interconnect structure 165.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming the polymer hybrid bond structures, the bonding strength of the bonding is improved. Since polymer layers are formed before the flow processes, the shapes and locations of the solder regions are defined by the polymer layers, and the bridging of solder regions is eliminated.

In accordance with some embodiments of the present disclosure, a method comprises forming a first package component comprising a first polymer layer; and a first electrical connector, with at least a part of the first electrical connector being in the first polymer layer; forming a second package component comprising a second polymer layer; and a second electrical connector, with at least a part of the second electrical connector being in the second polymer layer; and bonding the first package component to the second package component, with the first polymer layer being bonded to the second polymer layer, and the first electrical connector being bonded to the second electrical connector.

In an embodiment, the first polymer layer comprises a first polymer chain, and the second polymer layer comprises a second polymer chain, and wherein the first polymer chain and the second polymer chain are joined to form a long polymer chain. In an embodiment, the first electrical connector and the second electrical connector are bonded through solder bonding. In an embodiment, the bonding comprises putting the first package component into contact with the second package component; performing a pre-heating process at a first temperature; performing a solder reflowing process to reflow a solder region, wherein the solder reflowing process is performed at a second temperature higher than the first temperature; and performing an annealing process at a third temperature.

In an embodiment, the method further comprises, before the first package component is put into contact with the second package component, partially curing the first polymer layer and the second polymer layer, wherein in the annealing process, the first polymer layer and the second polymer layer are fully cured. In an embodiment, the first temperature is lower than a melting temperature of the solder region. In an embodiment, the first electrical connector and the second electrical connector are bonded through direct metal-to-metal bond. In an embodiment, the bonding comprises a pre-heating process at a first temperature; a heating process to form the direct metal-to-metal bond, wherein the heating process is performed at a second temperature higher than the first temperature; and an annealing process at a third temperature.

In an embodiment, the first electrical connector is recessed from the first polymer layer to form a recess, and the second electrical connector comprises a protruding portion protruding out of the second polymer layer, and wherein in the bonding, the protruding portion extends into the recess. In an embodiment, the recess is formed by processes comprising applying the first polymer layer, wherein a portion of the first polymer layer covers the first electrical connector; planarizing the first polymer layer; and performing a photolithography process to remove the portion of the first polymer layer. In an embodiment, the protruding portion is formed by processes comprising applying the second polymer layer, wherein a portion of the second polymer layer covers the second electrical connector; planarizing the second polymer layer; and etching back the second polymer layer.

In accordance with some embodiments of the present disclosure, a structure comprises a first package component comprising a first polymer layer; and a first electrical connector, with at least a part of the first electrical connector being in the first polymer layer; and a second package component comprising a second polymer layer bonding to the first polymer layer; and a second electrical connector, with at least a part of the second electrical connector being in the second polymer layer, wherein the first electrical connector is bonded to the second electrical connector.

In an embodiment, the first polymer layer and the second polymer layer comprise different polymers. In an embodiment, the first polymer layer and the second polymer layer comprise a same polymer material, and wherein the first polymer layer and the second polymer layer have a distinguishable interface. In an embodiment, the first polymer layer comprises a first polymer chain, and the second polymer layer comprises a second polymer chain, and wherein the first polymer chain and the second polymer chain are joined to form a long polymer chain. In an embodiment, the second electrical connector comprises a protruding portion in the first polymer layer.

In accordance with some embodiments of the present disclosure, structure comprises a first package component comprising a first surface dielectric layer; a first metal pillar protruding out of the first surface dielectric layer; and a first polymer layer encircling the first metal pillar; and a second package component comprising a second surface dielectric layer; a second metal pillar protruding out of the second surface dielectric layer; and a second polymer layer encircling the second metal pillar, wherein the first metal pillar is electrically coupled to the second metal pillar, and wherein the second metal pillar further extends into the first polymer layer.

In an embodiment, the structure further comprises a solder region physically joining the first metal pillar to the second metal pillar, wherein the solder region includes at least a part in the first polymer layer. In an embodiment, the first metal pillar comprises first straight sidewalls contacting the first polymer layer, and the solder regions comprise second straight sidewalls contacting the first polymer layer. In an embodiment, the second straight sidewalls are aligned to the first straight sidewalls.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first package component comprising:
a first polymer layer; and
a first electrical connector, with at least a part of the first electrical connector being in the first polymer layer;
forming a second package component comprising:
a second polymer layer; and
a second electrical connector, with at least a part of the second electrical connector being in the second polymer layer; and
bonding the first package component to the second package component, with the first polymer layer being bonded to the second polymer layer, and the first electrical connector being bonded to the second electrical connector.

2. The method of claim 1, wherein the first polymer layer comprises a first polymer chain, and the second polymer layer comprises a second polymer chain, and wherein the first polymer chain and the second polymer chain are joined to form a long polymer chain.

3. The method of claim 1, wherein the first electrical connector and the second electrical connector are bonded through solder bonding.

4. The method of claim 3, wherein the bonding comprises:
putting the first package component into contact with the second package component;
performing a pre-heating process at a first temperature;
performing a solder reflowing process to reflow a solder region, wherein the solder reflowing process is performed at a second temperature higher than the first temperature; and
performing an annealing process at a third temperature.

5. The method of claim 4 further comprising, before the first package component is put into contact with the second package component, partially curing the first polymer layer and the second polymer layer, wherein in the annealing process, the first polymer layer and the second polymer layer are fully cured.

6. The method of claim 4, wherein the first temperature is lower than a melting temperature of the solder region.

7. The method of claim 1, wherein the first electrical connector and the second electrical connector are bonded through direct metal-to-metal bond.

8. The method of claim 7, wherein the bonding comprises:
a pre-heating process at a first temperature;
a heating process to form the direct metal-to-metal bond, wherein the heating process is performed at a second temperature higher than the first temperature; and
an annealing process at a third temperature.

9. The method of claim 1, wherein the first electrical connector is recessed from the first polymer layer to form a recess, and the second electrical connector comprises a protruding portion protruding out of the second polymer layer, and wherein in the bonding, the protruding portion extends into the recess.

10. The method of claim 9, wherein the recess is formed by processes comprising:
applying the first polymer layer, wherein a portion of the first polymer layer covers the first electrical connector;
planarizing the first polymer layer; and
performing a photolithography process to remove the portion of the first polymer layer.

11. The method of claim 9, wherein the protruding portion is formed by processes comprising:
applying the second polymer layer, wherein a portion of the second polymer layer covers the second electrical connector;
planarizing the second polymer layer; and
etching back the second polymer layer.

12. A structure comprising:
a first package component comprising:
a first polymer layer; and
a first electrical connector, with at least a part of the first electrical connector being in the first polymer layer; and
a second package component comprising:
a second polymer layer bonding to the first polymer layer; and
a second electrical connector, with at least a part of the second electrical connector being in the second polymer layer, wherein the first electrical connector is bonded to the second electrical connector.

13. The structure of claim 12, wherein the first polymer layer and the second polymer layer comprise different polymers.

14. The structure of claim 12, wherein the first polymer layer and the second polymer layer comprise a same polymer material, and wherein the first polymer layer and the second polymer layer have a distinguishable interface.

15. The structure of claim 12, wherein the first polymer layer comprises a first polymer chain, and the second polymer layer comprises a second polymer chain, and wherein the first polymer chain and the second polymer chain are joined to form a long polymer chain.

16. The structure of claim 12, wherein the second electrical connector comprises a protruding portion in the first polymer layer.

17. A structure comprising:
a first package component comprising:
a first surface dielectric layer;
a first metal pillar protruding out of the first surface dielectric layer; and
a first polymer layer encircling the first metal pillar; and
a second package component comprising:
a second surface dielectric layer;
a second metal pillar protruding out of the second surface dielectric layer; and
a second polymer layer encircling the second metal pillar, wherein the first metal pillar is electrically coupled to the second metal pillar, and wherein the second metal pillar further extends into the first polymer layer.

18. The structure of claim 17 further comprising a solder region physically joining the first metal pillar to the second metal pillar, wherein the solder region includes at least a part in the first polymer layer.

19. The structure of claim 18, wherein the first metal pillar comprises first straight sidewalls contacting the first polymer layer, and the solder regions comprise second straight sidewalls contacting the first polymer layer.

20. The structure of claim 19, wherein the second straight sidewalls are aligned to the first straight sidewalls.
